(19) United States
(12) Patent Application Publication
(10) Pub. No.: US 2006/0065194 A1
(43) Pub. Date: Mar. 30, 2006

(54) Diffuser and semiconductor device manufacturing equipment having the same

(76) Inventor: Tae-Seok Ham, Yongin-si (KR)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/214,940

(22) Filed: Aug. 31, 2005

(30) Foreign Application Priority Data
Sep. 22, 2004 (KR) 2004-75760

(51) Int. Cl. C23C 16/00; H01L 21/677; C23C 14/00; B05B 1/14

(52) U.S. Cl. 118/715; 118/719; 239/554; 414/217; 204/298.35

(57) ABSTRACT

Semiconductor device manufacturing equipment includes a plurality of process chambers in which one or more fabrication processes takes place, a transfer chamber selectively communicating with the process chambers by means of doors, a vacuum pump and a source of vent gas which are connected to the transfer chamber via vacuum/vent lines to regulate the (vacuum) pressure in the transfer chamber, and a respective diffuser connected to at least one of the vacuum/vent lines. The diffuser includes a tube connected in series with the line and having a plurality of radial through-holes, a case including a cylindrical support surrounding the tube as spaced from the tube, and a particulate filter extending along an inner surface of the case. The cylindrical support has a plurality of pores smaller than the holes in the tube. The filter, on the other hand, has a plurality of micro pores smaller than the pores of the support.

### BACKGROUND OF THE INVENTION

1. Field of the Invention

The present invention relates to equipment for manufacturing a semiconductor device. More particularly, the present invention relates to a diffuser for diffusing gas introduced into a vacuum transfer chamber and to semiconductor device manufacturing equipment having the same.

2. Description of the Related Art

In general, a semiconductor device is manufactured by selectively and repeatedly carrying out fabrication processes on a wafer. These fabrication processes include deposition, photolithography, etching, diffusion, and ion implantation processes and the like. To this end, the wafer is transferred from a cassette, loaded with several of the wafers, to respective units for performing the fabrication processes. Accordingly, semiconductor device manufacturing equipment typically has a multi-chamber structure comprising a plurality of processing chambers in which the wafers are processed.

Conventional semiconductor device manufacturing equipment having a multi-chamber structure will be described with reference to FIG. 1. This semiconductor device manufacturing equipment is of a cluster-type that includes a cluster of process chambers 10 in which at least one type of fabrication process is performed on wafers, and a common transfer chamber 20 to which the process chambers 10 are connected. In the case in which one or more fabrication processes such as plasma reaction, etching, and CVD are performed in the process chambers 10, a vacuum is established in the process chambers 10 by means of a high performance vacuum pump (for example, a turbo pump).

In addition to the process chambers 10, the transfer chamber 20 is connected to load lock chambers 30, an aligning chamber 40 disposed adjacent to the load lock chambers 30 for aligning the wafers before the wafers are processed in the process chamber 10, a cooling chamber 50 for cooling the wafers that have been processed in the process chambers 10, and a cleaning chamber 60 for ashing or cleaning the wafers that have been processed in the process chambers 10. The wafer cassettes are loaded into the load lock chambers 30. The wafers are thus introduced into and withdrawn from the semiconductor manufacturing equipment via the load lock chambers 30.

A respective door 70 is installed between the transfer chamber 20 and each of the chambers 10, 30, 40, 50 and 60 connected thereto. Each door 70 is opened and closed by a controller. A robotic arm 80 is disposed in the transfer chamber 20 for unloading the wafers one-by-one from a wafer cassette and transferring the wafers to desired positions in the equipment. One or more wafer supports 82, e.g., vacuum chucks, are connected to the robotic arm.

The transfer chamber 20 is maintained at almost atmospheric pressure when a wafer is transferred by the robotic arm 80 from or into a load lock chamber 30. On the other hand, the transfer chamber 20 is maintained in a low vacuum state when a wafer is transferred by the robotic arm 80 into a process chamber 10. At that time, the transfer chamber 20 is evacuated by means of a vacuum pump (for example, a dry pump) communicating with a vacuum hole 24 at the bottom of the transfer chamber 20. In addition, once the door 70 interposed between the transfer chamber 20 and the process chamber 10 is opened, air flows from the transfer chamber 20 to the process chamber 10 because the internal pressure of the process chamber 10 is lower than that of the transfer chamber 20. Consequently, fine particles are prevented from entering the transfer chamber 20 from the process chamber. Moreover, the transfer chamber 20 is supplied with a vent gas (for example, nitrogen gas) via a vent hole 22 at the bottom of the transfer chamber 20 to maintain the internal pressure of the transfer chamber 20 above that of the process chamber 10.

However, fine particles adhering to the wafer can separate from the wafer as the wafer is being transferred from the process chamber 10 into the transfer chamber 20. In this case, the particles may remain in the transfer chamber 20 or migrate to the load lock chamber(s) 30. In particular, the fine particles are likely to separate from the wafer if the vent gas flowing into the transfer chamber 20 is turbulent.

Therefore, a diffuser 200 (FIG. 2) is installed over the vent hole 22 to prevent eddies from occurring in the vent gas flowing into the transfer chamber 20. Such a diffuser for regulating the flow of gas into a vacuum chamber is disclosed in U.S. Pat. No. 6,663,025.

As shown in FIG. 2, the diffuser 200 includes a body 202, a deflector 204, a spider 206, and a pair of guide vanes 210 and 212. The body 202 has a nozzle 302 at a central portion thereof. The nozzle 302 is connected to a vacuum/vent line through which a vent gas flows. The deflector 204 is disposed over the central portion of the body 202 for deflecting the vent gas flowing through the nozzle 302. The guide vanes 210 and 212 are interposed between the body 202 and the deflector 204 so as to guide the vent gas deflected back towards the body 202 by the deflector 204.

The nozzle 302 is a unitary part of the body 202 or may be a discrete member that is connected to the body 302. In either case, the nozzle 302 has a nozzle opening that tapers; the portion of the nozzle opening adjacent the body 202 is wider than the portion of the nozzle opening that is connected to the vacuum/purge line. Also, the body 202 has a rounded upper surface. In this respect, a portion of the upper surface adjacent the nozzle 302 has a relatively steep slope compared to the portion of the upper surface that is remote from the nozzle 302.

The deflector 204 covers the nozzle 302 and a portion of the body 202 adjacent the nozzle 302 and is configured to reverse the direction of flow of the vent gas issuing from the nozzle 302. Also, the deflector 204 protrudes toward the center of the nozzle 302 so as to uniformly distribute the vent gas issuing from the nozzle 302 towards the entire portion of the upper surface of the body 202 adjacent the nozzle 302.

More specifically, as the gas is injected into the transfer chamber 20 through the nozzle 302, the gas is first allowed to expand within the nozzle 302 and at the deflector 204, and is secondarily allowed to expand as it passes over the upper surface of the body 202. As a result, eddies are prevented from occurring in the vent gas introduced into the transfer chamber 20. Similarly, when the vacuum pump operates to create a vacuum in the transfer chamber 20, eddies are prevented from being generated in the gas flowing from the transfer chamber 20. In addition, there is a difference between the pressure of the vent gas flowing over the portion of the body 202 adjacent the deflector 204 and the pressure of the vent gas flowing over the portion of the body 202 remote from the nozzle 302. However, the guide vanes 210 and 212 prevent such a pressure difference from producing eddies in the vent gas.

Nonetheless, the diffuser 200 of the prior art has the following problems. First, a wafer may be misaligned on or released from the robotic arm 80 by the vent gas as the robotic arm 80 passes over the diffuser 200 in the transfer chamber 20. This causes a reduction in the production yield. Second, the pressure in the transfer chamber 20 is periodically changed from a low degree of vacuum pressure to a high degree of vacuum pressure. During this time, any fine particles that are present in the transfer chamber 20 enter the vacuum/vent line through the diffuser 70, and re-enter the transfer chamber 20 when the transfer chamber 20 is vented. As a result, any wafer that is present in the transfer chamber 20 at this time is contaminated.

### SUMMARY OF THE INVENTION

Therefore, an object of the present invention is to provide a diffuser, and manufacturing equipment comprising the same, that help maximize the yield of products fabricated in a vacuum atmosphere.

A more specific object of the present invention is to provide a diffuser capable of preventing a substrate disposed above the diffuser on a robotic arm from being misaligned or released by vent gas supplied through the diffuser. Likewise, an object of the present invention Is to provide manufacturing equipment comprising such a diffuser.

Another more specific object of the present invention is to provide a diffuser capable of preventing pollutants from entering or exiting a vacuum chamber, such as a transfer chamber, via a vacuum and/or a vent line connected to the vacuum chamber. Similarly, another specific object of the present invention is to provide manufacturing equipment comprising such a diffuser.

According to one aspect of the present invention, there is provided a diffuser comprising: a tube having a plurality of radial through-holes, a case having a cylindrical support that encloses the tube, is radially spaced apart from the tube by a desired interval, and has a plurality of pores smaller than the holes in the tube in terms of their cross-sectional areas, and at least one filter extending over an inner surface of the case and defining a plurality of micro pores smaller than the pores of the case in terms of their average diameters.

According to another aspect of the invention, there is provided manufacturing equipment for use in processing a substrate, comprising: a vacuum chamber, and a pressure regulating system connected to the chamber so as to regulate the pressure within the chamber, wherein the pressure regulating system includes a gas flow line extending into the chamber and having a distal end through which gas is forced, and a diffuser as described above disposed within the chamber and connected to the distal end of the gas flow line. In this case, the tube of the diffuser extends in series with the gas flow line.

According to yet another aspect of the present invention, there is provided equipment for processing a substrate, comprising: a plurality of process chambers in which at least one type of process is carried out on a substrate, a transfer chamber that can be selectively placed in communication with the process chambers by respective doors, a vacuum pump and a vent gas supply source connected to the transfer chamber via vacuum/vent lines to regulate the (vacuum) pressure in the transfer chamber, and a respective diffuser as described above disposed within the transfer chamber and connected to at least one of the vacuum/vent lines. In this case as well, the tube of the diffuser extends in series with the line.

According to still yet another aspect of the present invention, there is provided equipment for processing a substrate, comprising: a plurality of process chambers in which at least one type of process is carried out on a substrate, a transfer chamber that can be selectively placed in communication with process chambers by respective doors, a vacuum pump and a vent gas supply source connected to the transfer chamber via vacuum/vent lines to regulate the (vacuum pressure) in the transfer chamber, and a respective diffuser disposed in the transfer chamber as connected to at least one of the vacuum/vent lines, wherein the diffuser includes a filter.

The filter of the diffuser according to the present invention preferably preferably comprises a film of aluminum oxide. Also, the filter preferably has a first layer whose pores have an average diameter of substantially 0.2 μm, 0.5 μm, or 0.8 μm, and a second layer whose pores have an average diameter of substantially 1 μm. Also, the first layer of the filter preferably has a thickness of about 20 μm.

### BRIEF DESCRIPTION OF THE DRAWINGS

The above and other features and advantages of the present invention will become more apparent to those of ordinary skill in the art from the following detailed description of the preferred embodiments thereof made with reference to the attached drawings in which:

FIG. 1 is a top schematic view of conventional semiconductor device manufacturing equipment having a multi-chamber structure;

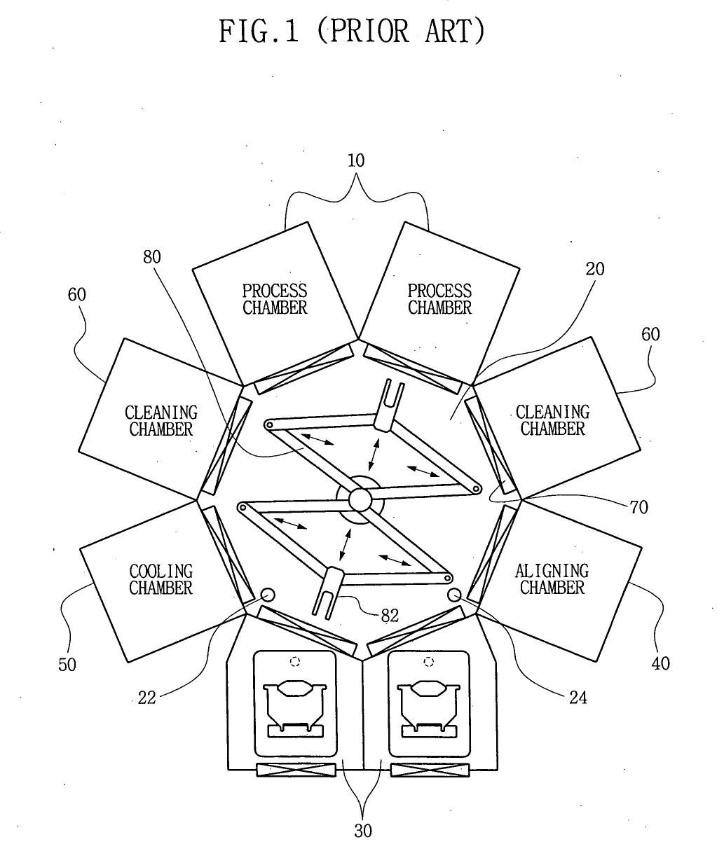

FIG. 2 is a cross-sectional view of a diffuser of the prior art;

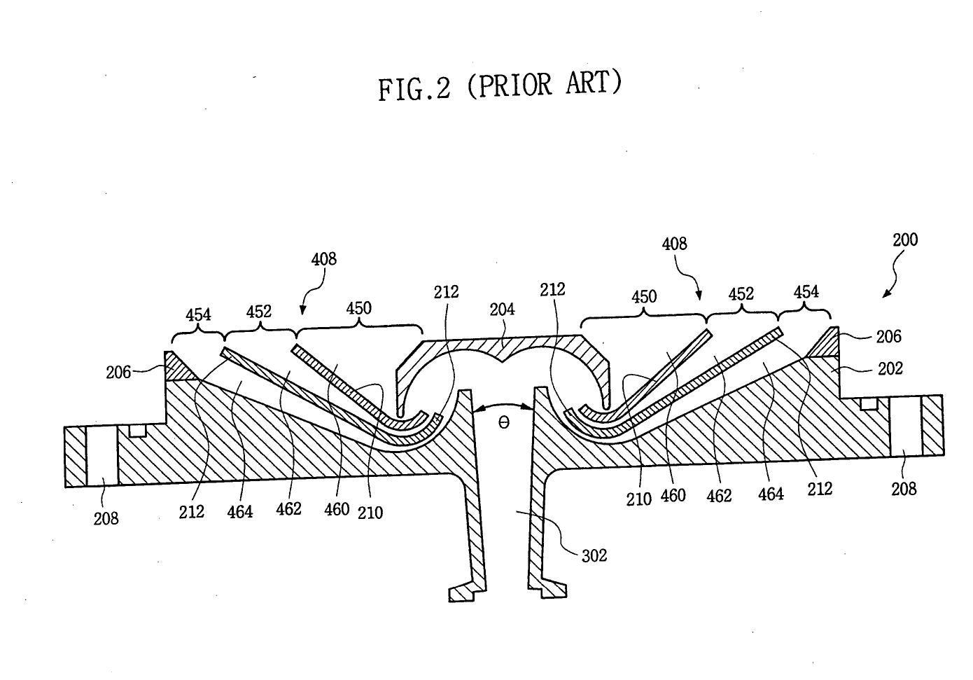

FIG. 3 is a top schematic view of semiconductor device manufacturing equipment according to the present invention;

FIG. 4 is a cross-sectional view of a transfer chamber, vacuum system and venting system of the semiconductor device manufacturing equipment shown in FIG. 3; and

FIG. 5 is a cross-sectional view of a diffuser of the semiconductor device manufacturing equipment according to the present invention.

### DETAILED DESCRIPTION OF THE PREFERRED EMBODIMENTS

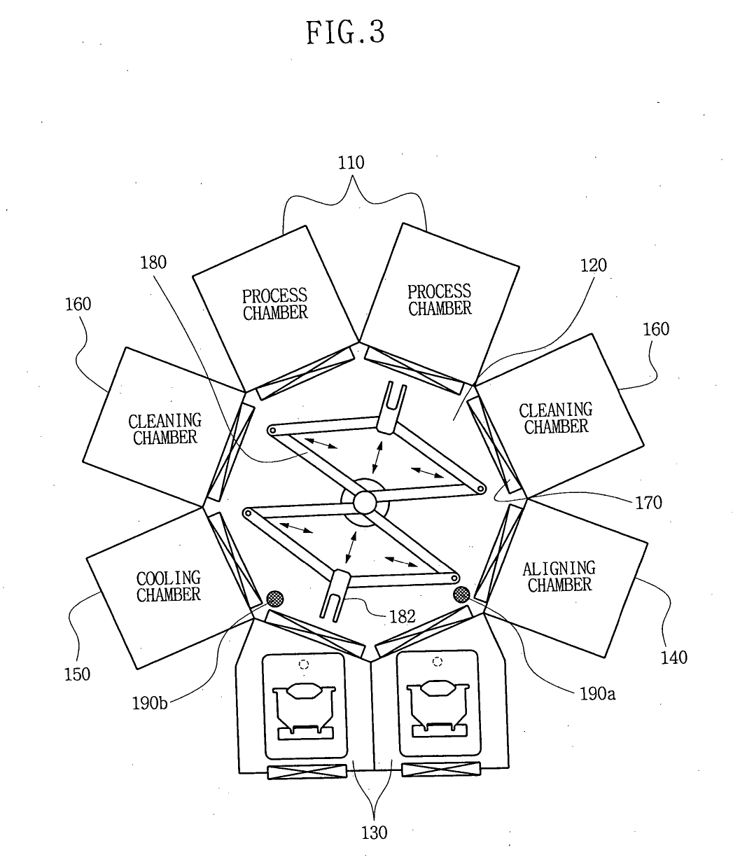

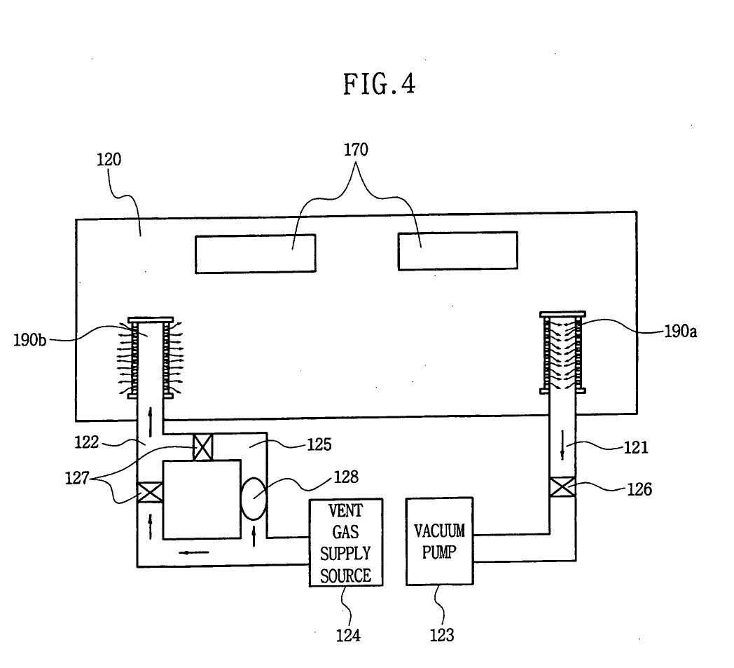

The present invention will now be described more fully hereinafter with reference to FIGS. 3-5.

The semiconductor device manufacturing equipment according to the present invention includes a plurality of process chambers 110 in which at least one type of semiconductor device fabrication process, such as an etching or deposition process, is carried out, a transfer chamber 120 to which the process chambers 110 are connected, a robotic arm 180 disposed in the transfer chamber for transferring wafers to and from predetermined positions in the equipment, doors 170 that can be opened and closed to selectively place the process chambers 110 in communication with the transfer chamber, and a pressure regulating system for regulating the pressure in the transfer chamber 120.

The pressure regulating system includes both a vacuum system for evacuating the transfer chamber 120, and a venting system for increasing the pressure within the transfer chamber 120. The vacuum system includes a vacuum line 121 terminating at the bottom of the transfer chamber 120, a vacuum pump 123 connecting to the transfer chamber 120 via the vacuum line, and a diffuser 190a protruding into the transfer chamber 120 at a distal end of the vacuum line 121. The venting system includes a vent line 122 terminating at the bottom of the transfer chamber 120, a vent gas supply source 124 connected to the transfer chamber 120 via the vent line 121, and a diffuser 190b protruding into the transfer chamber 120 at a distal end of the vent line 122, the diffusers 190a, 190b serve to attenuate the pressure of vent gas and exhaust gas and filter pollutants contained in the vent gas and the exhaust gas.

The semiconductor manufacturing equipment may also include load lock chambers 30 connected to the transfer chamber 120 and through which wafers are introduced into and unloaded from the equipment, an aligning chamber 140 disposed adjacent a load lock chamber 130 for aligning the wafers before the wafers are processed in a process chamber 110, a cooling chamber 150 for cooling the wafers processed in the process chambers 110, and cleaning chambers 160 for ashing or cleaning wafers that have been processed in the process chambers 110. Also, the semiconductor manufacturing equipment includes a pressure sensor (not shown) for measuring the degree of vacuum in the transfer chamber 120, and a controller (not shown) for controlling the doors 170 and various valves provided in the vacuum/vent lines 121 and 122 in accordance with signals output from the pressure sensor.

The robotic arm 180 unloads the wafers one-by-one from a wafer cassette disposed in a load lock chamber 130 and transfers them to desired positions under the command of the controller. One portion or end of the robotic arm 180 is rotatably supported at the center of the transfer chamber 120, and one or more wafer supports, e.g., wafer chucks, are connected to other end or portions of the robotic arm 180. Each wafer support 182 is configured to support a wafer and hold the wafer steady during its transfer. The robotic arm 180 has a working envelope that encompasses the various chambers so that it may loading or unload a wafer into or from the chamber that is communicating with the transfer chamber 120.

The pressure in the transfer chamber 120 is maintained at almost atmospheric pressure when the wafer is loaded into or unloaded from a wafer cassette disposed in a load lock chamber 130. On the other hand, a low vacuum state is maintained in the transfer chamber 120 when the wafer is loaded from the transfer chamber 120 into a process chamber 110 in which a high vacuum state exists.

Specifically, the transfer chamber 120 is evacuated by the vacuum pump 123 via the diffuser 190a connected to vacuum line 121. The diffuser 190a is located at the bottom of the transfer chamber 120 between a load lock chamber 130 and the aligning chamber 140. Agate valve 126 is disposed in the vacuum line 121 for regulating the amount of gas or air exhausted from the transfer chamber 120 according to a control signal output from the controller. However, once the degree of vacuum in the transfer chamber 120 becomes higher than that in a process chamber 110 into which a wafer is to be transferred (or from which the wafer is to be transferred), the transfer chamber 120 is supplied with a vent gas via the diffuser 190b. The diffuser 190b is located at the bottom of the transfer chamber 120 between a load lock chamber 130 and the cooling chamber 150.

The venting system can supply a constant amount of gas into the transfer chamber 120 to increase the pressure in the transfer chamber from a low vacuum pressure to atmospheric pressure. Also, the vent line 122 has a slow venting section 125 configured as a bypass in the vent line 122. A minute amount of vent gas is allowed into the transfer chamber 120 through the slow venting (bypass) section 125 of the vent line 122 while the transfer chamber 120 is in a low vacuum pressure state (for example, about 1.0 E⁻² Torr). To this end, a plurality of valves 127 controlled by the controller are disposed in the main section and the slow venting (bypass) section 125 of the vent line 122 so as to selectively supply the vent gas to the transfer chamber 120 through the main section and slow venting (bypass) section. Also, a pressure reducing device 128 such as a throttle valve or automatic pressure regulating valve is disposed in the slow venting (bypass) section 125.

The diffusers 190a, 190b according to the present invention each include a filter 193 capable of reducing the pressure of the gas flowing through the diffuser. Accordingly, when a wafer is positioned above the diffuser 190b in the transfer chamber 120 by the robotic arm 180, the vent gas issuing from the diffuser 190b will not cause the wafer to be released from the wafer support 182 or to become misaligned on the wafer support 182.

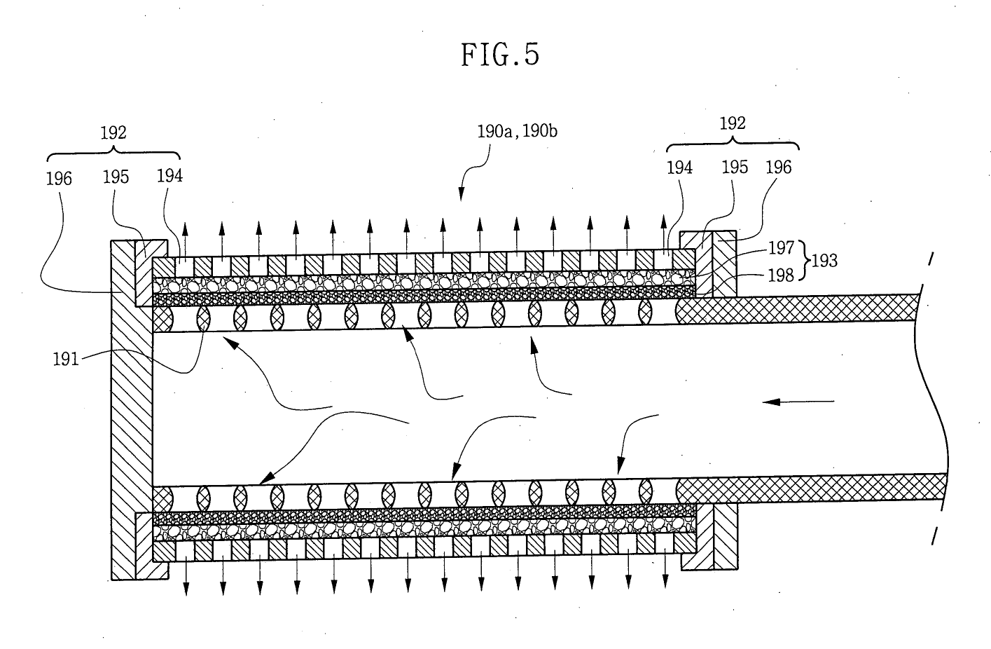

As shown in FIG. 5, the diffusers 190a and 190b each include a tube 191 connected to the respective vacuum/vent line 121 and 122 with a pipe fitting, a case 192 in which the tube 191 is enclosed as spaced therefrom, and a filter 193 interposed between the case 192 and the tube 191. The tube 191 has a plurality of holes through which gas can flow. The case 192 has a plurality of pores smaller than the holes in the tube 191 in terms of their cross-sectional areas. The filter 193, on the other hand, has a plurality of micro pores smaller than the pores in the case 192.

The case 192 includes a cylindrical support 194 that supports the filter 193 and encloses the tube 191, a spacer 196 closing both ends of the support 194, and a respective Teflon® (tetrafluoroethylene) gasket 195 interposed between the spacer 196 and each end of the support 114. The support 194 is made of ceramics, and the spacer 196 is made of metal. The filter is made of ceramics and preferably, of a film of aluminum oxide (Al₂O₃).

Also, the filter 193 has micro pores whose diameter (average diameter on the order over microns) is smaller than the (average) diameter of fine particles that can be present in the transfer chamber 120. For example, the filter 193 may have two layers consisting of a first filter layer 197 having fine pores that are 0.2 μm, 0.5 μm, or 0.8 μm in diameter, and a second filter layer 198 having fine pores of 1 μm in diameter. In this case, the first filter layer 197 has a thickness of about 20 μm, and the second filter layer 198 has a thickness of about 30 μm. The support 194 has a thickness of about 100 μm and pores that are about 15 μm in diameter. Also, the filter 193 may be supported as radially spaced from the tube 191 by a certain interval.

Thus, the filters 193 prevent pollutants from entering or exiting the vacuum/vent lines 121 and 122 connected to the transfer chamber 120. Hence, the diffusers 190a, 190b of the present invention prevent the wafers from being contaminated and thus contribute to maximizing the production yield.

Finally, the surface of the filter 193 can be been checked after the transfer chamber 120 has been supplied with the vent gas for a predetermined period of time. Specifically, an electron probe micro analyzer can be used to identify the pollutants on the filter 193. Therefore, the potential source of contamination of the wafers can be determined. For instance, if the pollutants on the surface of the filter 193 of diffuser 190b contain Fe or Al, then the various valves in the purge line 122 can be identified as the source of contamination because the valves are typically of materials comprising Fe or Al.

According to the present invention as described above, the diffuser includes a filter capable of reducing the pressure of the gas passing therethrough. Accordingly, when a wafer being transferred by the robotic arm in the transfer chamber is located above the diffuser connected to the vent line, the wafer will not become misaligned on or released from the wafer support by the venting gas. Also, the filter(s) prevent pollutants from entering or exiting the vacuum/vent lines connected to the transfer chamber. Thus, the diffusers prevent the wafers from being contaminated. Thus, the diffusers of the present invention contribute to maximizing the production yield of the semiconductor devices.

Finally, although the present invention has been described above with respect to the preferred embodiments thereof, it will be understood that the scope of the invention is not so limited. Rather, the invention includes various modifications and alternative arrangements of the preferred embodiments as will be apparent to persons skilled in the art. Accordingly, the true spirit and scope of the invention is not limited to the preferred embodiments but by the scope of the appended claims.

What is claimed is:

1. A diffuser for use in regulating the pressure of gas in a vacuum chamber, the diffuser comprising:
a tube having a plurality of holes extending radially therethrough;
a case enclosing said tube and having a cylindrical support surrounding and spaced radially from the tube, the support having a plurality of pores extending therethrough, the average cross-sectional area of said pores being smaller than the average cross-sectional area of the holes in the tube; and
a filter extending along an inner surface of the support of said case and defining a plurality of micro pores, the average diameter of the micro pores of said filter being smaller than that of the pores of the case.

2. The diffuser according to claim 1, wherein the filter comprises a film of aluminum oxide.

3. The diffuser according to claim 1, wherein the filter includes a first layer having pores whose average diameter is substantially one of 0.2 μm, 0.5 μm, or 0.8 μm, and a second layer having pores whose average diameter is substantially 1 μm.

4. The diffuser according to claim 3, wherein the first layer of the filter has a thickness of about 20 μm.

5. The diffuser according to claim 1, wherein the case is made of metal.

6. The diffuser according to claim 1, wherein the case further includes a spacer closing both ends of the cylindrical support, and a respective gasket interposed between the spacer and each end of the support.

7. The diffuser according to claim 6, wherein the support is of a ceramic material.

8. The diffuser according to claim 6, wherein the spacer is of metal.

9. The diffuser according to claim 6, wherein each said respective gasket is of tetrafluoroethylene.

10. Manufacturing equipment for use in processing a substrate, the equipment comprising:
a chamber; and
a pressure regulating system connected to the chamber so as to regulate the pressure within the chamber, said pressure regulating system including a gas flow line extending into the chamber and having a distal end through which gas is forced, and a diffuser disposed within the chamber and connected to-the distal end of the gas flow line, the diffuser including
a tube having a plurality of holes extending radially therethrough and extending in series with the gas flow line,
a case enclosing said tube and having a cylindrical support surrounding and spaced radially from the tube, the support having a plurality of pores extending therethrough, the average cross-sectional area of said pores being smaller than the average cross-sectional area of the holes in the tube, and
a filter extending along an inner surface of the support of said case and defining a plurality of micro pores, the average diameter of the micro pores of said filter being smaller than that of the pores of the case.

11. The manufacturing equipment according to claim 10, wherein the filter comprises a film of aluminum oxide.

12. The manufacturing equipment according to claim 10, wherein the filter includes a first layer having pores whose average diameter is substantially one of 0.2 μm, 0.5 μm, or 0.8 μm, and a second layer having pores whose average diameter is substantially 1 μm.

13. The manufacturing equipment according to claim 12, wherein the first layer of the filter has a thickness of about 20 μm.

14. The manufacturing equipment according to claim 10, wherein the pressure regulating system is a vacuum system and the gas flow line is a vacuum line, the pressure regulating system further including a vacuum pump connected to the vacuum line and operative to withdraw gas from the chamber via the diffuser.

15. The manufacturing equipment according to claim 10, wherein the pressure regulating system is a venting system and the gas flow line is a vent line, the pressure regulating system further including a source of gas connected to the vacuum line such that gas is introduced from the source into the chamber via the diffuser.

16. The manufacturing equipment according to claim 10, wherein the chamber is a transfer chamber, and further comprising a robotic arm disposed in the transfer chamber and operative to transfer substrates through the transfer chamber.

17. Manufacturing equipment for use in processing a substrate, the equipment comprising:
a plurality of process chambers in which at least one type of process is carried out on a substrate;
a transfer chamber to which each of the process chambers is connected;
a robotic arm disposed in the transfer chamber;
a respective door separating the interior of each of the process chambers from the interior of the transfer chamber;
a vacuum line connected to the transfer chamber;
a vent line connected to the transfer chamber;
a vacuum pump connected to the transfer chamber via the vacuum line, whereby gas can be evacuated from the transfer chamber via the vacuum line;
a source of vent gas connected to the transfer chamber via the vent line, whereby gas can be introduced into the transfer chamber via the vent line; and
a respective diffuser connected to at least one of the vacuum line and the vent line and disposed within the transfer chamber, each said respective diffuser including
a tube having a plurality of holes extending radially therethrough and extending in series with the line to which the diffuser is connected,
a case enclosing said tube and having a cylindrical support surrounding and spaced radially from the tube, the support having a plurality of pores extending therethrough, the average cross-sectional area of said pores being smaller than the average cross-sectional area of the holes in the tube, and
a filter extending along an inner surface of the support of said case and defining a plurality of micro pores, the average diameter of the micro pores of said filter being smaller than that of the pores of the case.

18. The equipment according to claim 17, wherein the filter comprises a film of aluminum oxide.

19. The equipment according to claim 17, wherein the filter includes a first layer having pores whose average diameter is substantially one of 0.2 μm, 0.5 μm, or 0.8 μm, and a second layer having pores whose average diameter is substantially 1 μm.

20. The equipment according to claim 19, wherein the first layer has a thickness of about 20 μm.

21. The equipment according to claim 17, wherein the case is made of metal.

22. The equipment according to claim 10, wherein the case further includes a spacer closing both ends of the cylindrical support, and a respective gasket interposed between the spacer and each end of the support.

23. Manufacturing equipment for use in processing a substrate, the equipment comprising:
a plurality of process chambers in which at least one type of process is carried out on a substrate;
a transfer chamber to which each of the process chambers is connected;
a robotic arm disposed in the transfer chamber;
a respective door separating the interior of each of the process chambers from the interior of the transfer chamber;
a vacuum line connected to the transfer chamber;
a vent line connected to the transfer chamber;
a vacuum pump connected to the transfer chamber via the vacuum line, whereby gas can be evacuated from the transfer chamber via the vacuum line;
a source of vent gas connected to the transfer chamber via the vent line, whereby gas can be introduced into the transfer chamber via the vent line; and
a respective diffuser connected to at least one of the vacuum line and the vent line and disposed within the transfer chamber, each said respective diffuser including a filter defining a plurality of micro pores.
